(19) United States
(12) Patent Application Publication
(10) Pub. No.: US 2005/0270730 A1
(43) Pub. Date: Dec. 8, 2005

(54) Extendable multi-screen flat panel (computer / television) monitor enabling increased workspace and viewable monitor surface

(76) Inventors: Alexander Ivanovich Klushin, Katy, TX (US); Brenda Fay Klushin, Katy, TX (US)

Correspondence Address: Alexander Klushin, 22527 Sail Harbour Ct., Katy, TX, 77450, US

(21) Appl. No.: 10/859,399

(22) Filed: Jun. 2, 2004

(51) Int. Cl. H05K 5/00

(52) U.S. Cl. 361/681

(57) ABSTRACT

This invention is an extendable multi-screen flat panel (computer/television) monitor enabling increased workspace and viewable monitor surface. This invention increases the viewable size of flat panel monitors of any kind by adding extendable monitor screens (display devices) on any or all sides of the primary monitor.

This invention is an extendable multi-screen flat panel (computer/television) monitor enabling increased workspace and viewable monitor surface. This invention increases the viewable size of flat panel monitors of any kind by adding extendable monitor screens (display devices) on any or all sides of the monitor.

In making use of this invention, a person skilled in the art would incorporate this invention into the design of a traditional flat panel monitor using various types of attaching mechanisms. An attaching mechanism would allow extendable screens to be partially or completely concealed when not in use by way of their design and placement on the primary display device. These attaching mechanisms can be located either internally or externally on the primary display device. When in use, the extendable display device is moved to its operable position at the terminal end of the attaching mechanism. Once in an operable position, the extendable portion of the display device would ideally remain flexible in movement, so as to be adjustable by the user to a desired viewable position.

The various depictions described in the detailed description to follow are provided by way of illustration only and should not be construed to limit the invention. Those skilled in the art will readily recognize various modifications and changes that may be made to the present invention without following the examples and applications illustrated and described herein, and without departing from the true spirit and scope of the present invention.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### FIELD OF INVENTION

This invention relates to the field of computer technology. It is an improvement on already existing display systems, defined by the U.S. patent classification as systems that comprise display terminals or display devices.

### BACKGROUND OF INVENTION

Various types of flat panel monitors are known in the art. Primary uses of flat panel monitors are for desktop computers, laptop/notebook computers and televisions. In this regard, the use of multiple monitors to view an image is also known, as in the case of large TV walls that break up an image and display it across multiple monitor screens.

It is also know that multiple independent display devices are connected to a single video card of a CPU to increase viewable work space. The problem with this is the amount of physical space required for multiple devices (computer monitors) to be functional for a user.

Due to increasing demands by users and growing amounts of information, independently existing computer monitors, including laptop and desktop flat panels, are limited in size and present a problem for users to view multiple pieces of information simultaneously. This invention is intended to improve this with the use of multiple expandable display devices.

### BRIEF SUMMARY OF INVENTION

This invention is an extendable multi-screen flat panel (computer/television) monitor enabling increased workspace and viewable monitor surface.

This invention applies to any flat panel monitor. The most applicable use is to notebook (laptop) and desktop computer flat panel monitors, as well as TV enabled monitors. It can be designed in many ways, including fold/flip-out or slide-out, but is not limited by such.

Because of the growing amount of information needed to be processed by individuals and the ability of computers to perform multiple tasks at the same time, this invention is intended to improve a person's efficiency by making information available on one or more than one extendable display screens.

### BRIEF DESCRIPTION OF THE SEVERAL VIEWS OF THE DRAWING

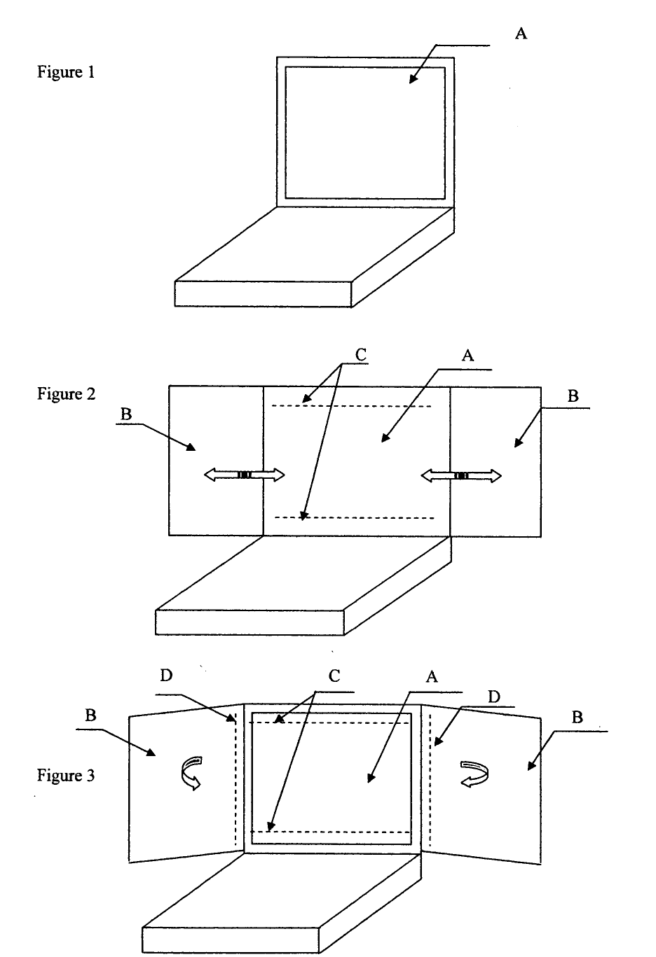

FIG. 1: appearance of a traditional opened laptop computer with primary monitor visible, and extendable portion of display device hidden.
A: primary monitor

FIG. 2: Laptop computer with extendable portion of display device partially extended
A: primary monitor
B: Extendable portion of display device
C: sliding mechanism (attaching mechanism)

FIG. 3: Laptop computer with extendable portion of display device fully extended
A: primary monitor
B: Extendable portion of display device
C: sliding mechanism (attaching mechanism)
D: adjusting mechanism

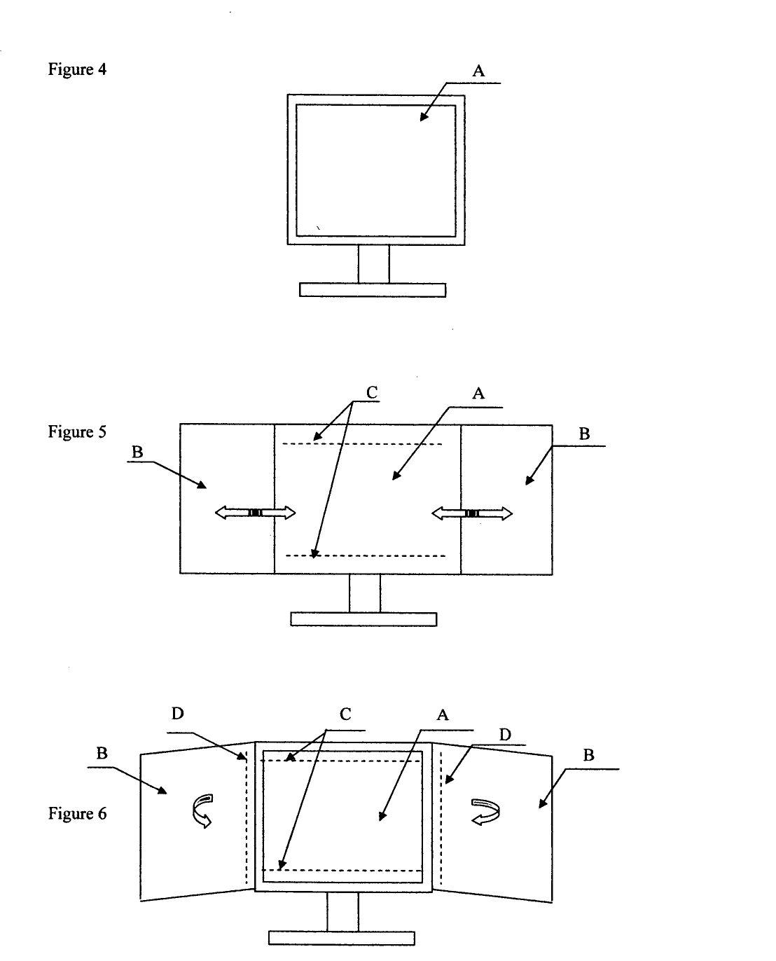

FIG. 4: appearance of a traditional flat panel monitor with extendable portion of display device hidden.
A: primary monitor

FIG. 5: Flat panel monitor extendable portion of display device partially extended
A: primary monitor
B: Extendable portion of display device
C: attaching mechanism

FIG. 6: Flat panel monitor with extendable portion of display device fully extended
A: primary monitor
B: Extendable portion of display device
C: attaching mechanism
D: adjusting mechanism

### DETAILED DESCRIPTION OF THE INVENTION

This invention is an extendable multi-screen flat panel (computer/television) monitor enabling increased workspace and viewable monitor surface. Because of the growing amount of information needed to be processed by individuals and the ability of computers to perform multiple tasks at the same time, this invention is intended to improve a person's efficiency by making information available on one or more than one extendable display screens.

This invention applies to any flat panel monitor. The most applicable use is to notebook (laptop) and desktop computer flat panel monitors, as well as TV enabled monitors. It can be designed in many different ways, including fold/flip-out or slide-out, but is not limited by such.

Notebook computers have a definite limitation on size. In making a notebook according to this invention, it enables the notebook monitor to be expanded to a greater viewing size during usage time and folded for storage. A notebook computer can still be used with only its primary monitor, as the extendable portion needs only be utilized when additional viewable monitor and work space is needed (FIG. 1).

In making use of this invention, a person skilled in the art would incorporate this invention into the design of a traditional flat panel monitor. One method of proposed application for use on a notebook (laptop) flat panel monitor is for the extendable portion of the display device to be positioned behind the primary monitor screen (FIG. 1A) and slide out when in use (FIG. 2). In such a case, there would be an internally mounted sliding mechanism (FIG. 3C) that would allow such movement of the extendable portion of the display device (FIG. 3B). Once extended for use (FIG. 3), the extendable portion of the display device (FIG. 3B) would ideally be independently adjustable from the primary monitor. This would mean that the extendable portion of the display device (FIG. 3B) can tilt in multiple directions regardless of the primary monitor position and adjustment. This would be accomplished with the use of an adjusting mechanism (additional sliding mechanism, various hinge mechanisms, rotating mechanism) that would be located at the terminal end of the embodied sliding mechanism (FIG. 3D).

Desktop flat panel monitors benefit from this invention, as well. As with the notebook computer, the monitor can be expanded (FIG. 6) when necessary and still not take space away from a desk area when not in use (FIG. 4). An attaching mechanism (FIG. 6C) would allow extendable screens (FIG. 6B) of the same or different size to be partially or completely concealed when not in use by way of their design and placement on the primary display device (FIG. 6A). These attaching mechanisms can be located either internally or externally on the primary display device (FIG. 4A). In drawing there is an external attaching mechanism (FIG. 6C) that allows the extendable portion of the display device to be moved from a nonworking to working position (FIG. 5). Once fully extended (FIG. 6), the extendable portion of the display device (FIG. 6B) would be locked in place at the terminal end of the attaching mechanism (FIG. 6C). Once in an operable position, the extendable portion of the display device (FIG. 6B) would ideally remain flexible in movement, so as to be adjustable by the user to a desired viewable position. Just as in the example of the notebook (laptop) design above, this would be accomplished with the use of an adjusting mechanism (additional sliding mechanism, various hinge mechanisms, rotating mechanism) that would be located at the terminal end of the attaching mechanism (FIG. 6D).

The extendable multi-screen flat panel monitor substantially maintains the appearance of the traditional flat panel monitor counterpart when not extended for full use.

The various embodiments described above are provided by way of illustration only and should not be construed to limit the invention. Those skilled in the art will readily recognize various modifications and changes that may be made to the present invention without following the example embodiments and applications illustrated and described herein, and without departing from the true spirit and scope of the present invention, which is set forth in the following claims

1. What we claim as our invention is an extendable multi-screen flat panel (computer/television) monitor enabling increased workspace and viewable monitor surface by adding extendable monitor screens (display devices) on any or all sides of a primary monitor, whereby; multiple attaching mechanisms are located externally on the primary display device; extendable portion of display device becomes operable when fully extended to the terminal end of the attaching mechanism; in an operable position the extendable portion(s) of the display device is independently adjustable and independently viewable (multiple viewing positions) from the primary monitor.

2. The display device in claim 1 wherein multiple attaching mechanisms are located internally on the primary display device.

3. The display device in claim 1 wherein when in an operable position the extendable portion(s) of the display device is independently adjustable and independently viewable (multiple viewing positions) from the primary monitor by use of additional attaching mechanisms, sliding mechanisms, hinge mechanisms or rotating mechanisms.
